(19) United States
(12) Patent Application Publication
(10) Pub. No.: US 2005/0142283 A1
(43) Pub. Date: Jun. 30, 2005

(54) Method for forming coated film, organic device using the same, and method for manufacturing electroluminescent element

(76) Inventor: Hiroshi Kishimoto, Tokyo (JP)

Correspondence Address: SEYFARTH SHAW, 55 EAST MONROE STREET, SUITE 4200, CHICAGO, IL, 60603-5803, US

(21) Appl. No.: 10/902,671

(22) Filed: Jul. 29, 2004

(30) Foreign Application Priority Data
Jul. 31, 2003 (JP) 2003-283298
Aug. 22, 2003 (JP) 2003-298349

(51) Int. Cl. B05D 7/00; B05D 5/12

(52) U.S. Cl. 427/66; 427/402

(57) ABSTRACT

It is an object of the present invention to avoid such a fault that the components of the coated film in the lower layer are included in the coated film in the upper layer, without an increase of the layer and without a requirement for a long time in the purification process for the materials. To achieve the above-described object, the present invention provides a method for forming a coated film for forming a coated film, wherein in forming the coated film onto a substrate, after impurities in a coating composition for forming the coated film are dissolved and removed in advance by using a solvent which can dissolve the impurities, the coated film is formed onto the substrate by using the coating composition in which the impurities are removed.

### BACKGROUND OF THE INVENTION

1. Field of the Invention

The present invention relates to a method for forming a coated film capable of inhibiting the elution of impurities or the like from a coated film in a lower layer, for example, in laminating and forming coated films. The present invention also relates to a method for manufacturing an organic device which uses the method for forming coated film described above.

2. Description of the Related Art

Organic devices which are formed by laminating a plurality of coated films onto a substrate have been attracting an attention. In using a coating method to laminate a plurality of the films, there is such an advantage that only simple equipment is required and a process time can be reduced, as compared to a vacuum film forming method in which vapor deposition or spattering is relied on for the lamination, or the like. In most cases, however, the lamination of the coated films is performed by coating, which uses a coating composition prepared by dissolving or dispersing film-forming components in an organic solvent. The organic solvent in the coating composition for forming an upper layer contacts a coated film in a lower layer, to thereby cause the elution of the components of the coated film in the lower layer. As a result, the components in the lower layer are included in a portion, which is located close to the lower layer, of the coated film in the upper layer, and in some cases, the functions of the upper and lower layers cannot be shown sufficiently. Moreover, the application of an electric current may transfer the impurities of the lower layer to the upper layer.

Even in the field of organic electroluminescent (EL) elements, the organic EL elements are broadly classified into two types; one is a polymer type in which a polymer material is used to form a light emitting layer or other layers by the coating, with the polymer material dissolving in an organic solvent, and the other is a low molecular type in which a low molecular material is used to prepare the layers in a vapor phase method, such as the vapor deposition. It is said that the organic EL elements of the polymer type tend to have a relatively short element lifetime, as compared to the organic EL elements of the low molecular type.

Conventionally, there is such a suggestion that a layer of a polymeric organic conductor layer is formed between an electrode and a light emitting layer by coating thereto a solution or dispersant containing particles with a diameter of 1 μm or less, to thereby inhibit brightness degradation (e.g. refer to Japanese Patent Application Laid-open No. 2000-91081). There is also such a suggestion that that a light emitting organic compound is purified several times to reduce the content of ionic impurities to 0.01 ppm or less, to thereby inhibit the brightness degradation (e.g. JP-A No. 2001-214159).

However, even in the method described in JP-A No. 2000-91081, a new layer is merely increased, and still, it is hardly possible to avoid the elution of the components of the coated film in the lower layer. In the method described in JP-A No. 2001-214159, it takes a long time to purify the materials. Moreover, in the organic EL element, a thin film of poly(3,4-ethylenedioxythiophene) doped with poly (styrene sulfonate) (a common name of PEDOT/PSS), which is frequently used on an Indium Tin Oxide (ITO) electrode layer, cuts off oxygen dispersing from ITO and increases the lifetime of a light emitting material, while corroding ITO by its acidity, so that there also arises the problem that indium transfers into the thin film.

### SUMMARY OF THE INVENTION

It is therefore an object of the present invention to avoid such a fault that the components of the coated film in the lower layer are included in the coated film in the upper layer, without an increase of the layer and without a requirement for a long time in the purification process for the materials. Moreover, it is an object of the present invention to provide a method for manufacturing the organic device which avoids the fault as described above.

The above objects of the present invention can be achieved by a method for forming a coated film, wherein in forming the coated film onto a substrate, after impurities in a coating composition for forming the coated film are dissolved and removed in advance by using a solvent which can dissolve the impurities, the coated film is formed onto the substrate by using the coating composition in which the impurities are removed.

In the present invention, after the impurities in the coating composition for forming the coated film are dissolved and removed in advance by using the solvent, the coated film is formed, so that it is possible to inhibit the elution of the impurities from the coated film, and moreover, there is an advantage that there is no increase of the layer and no requirement for a long time in the purification process for the materials.

Moreover, in another aspect of the method for forming a coated film of the present invention, in forming at least two-layer coated films onto the substrate in order, after a coated film in a lower layer is formed by using the coating compositions in which the impurities are dissolved and removed, a coated film in an upper layer may be formed onto the coated film in the lower layer.

In the present invention, after the impurities in the coating composition for lower-layer formation are dissolved and removed by using the solvent, the coated film in the lower layer is formed, and then, the coated film in the upper layer is formed, so that it is possible to inhibit the elution of the impurities from the lower layer, in forming the upper layer, and moreover, there is an advantage that there is no increase of the layer and no requirement for a long time in the purification process for the materials.

In this case, the coated film in the upper layer may be formed by using the coating composition in which the impurities are dissolved and removed. This is because, for example, if a coated film in a third layer is laminated onto the coated film in the upper layer, it is possible to inhibit the elution of the impurities from the upper layer, in forming the third layer.

In the above-descried present invention, it is preferable that the solvent which can dissolve the impurities is incompatible with a solvent in the coating composition. This is because, in addition to the above-described effects, the solvent which can dissolve and remove the impurities is incompatible with a solvent in the coating composition which is the object of dissolving and removing the impurities, which facilitates the separation of the solvents used in the dissolution and removal of the impurities.

Moreover, in the present invention, it is preferable that the coating composition contains polymer which may include low molecular components as impurities, and the solvent which can dissolve the impurities does not dissolve the polymer. This is because, in addition to the above-described effects, the coating composition which is the object of dissolving and removing the impurities contains polymer, and that the use of the solvent which does not dissolve the polymer in the dissolution and removal of the impurities, allows the dissolution and removal of the impurities without destroying the polymer in the lower layer.

The above objects of the present invention can be also achieved by a method for manufacturing an organic device comprising: a substrate; an electrode layer formed on the substrate; and an organic conductive layer which is formed on the electrode layer and which includes at least one-layer coated film, wherein the at least one-layer coated film of the organic conductive layer is formed by using the above-described method for forming a coated film.

In the present invention, the substrate with the electrode layer on its surface is used, and the above-described first method for forming a coated film is used in forming at least one-layer coated film thereon, to thereby allow the method for manufacturing the organic device to show the above-described effects.

Moreover, the above objects of the present invention can be also achieved by a method for manufacturing an organic electroluminescent (EL) element comprising: a substrate; an electrode layer formed on the substrate; an organic conductive layer which is formed on the electrode layer and which includes coated films of an electric charge injection/transportation layer and an organic light emitting layer formed on the electric charge injection/transportation layer; and a facing electrode layer which is formed on the organic conductive layer and which faces the electrode layer, wherein at least one of coated films of the electric charge injection/transportation layer and the organic light emitting layer is formed by using the above-described method for forming a coated film.

In the present invention, at least one of the coated films of the electric charge injection/transportation layer and the organic light emitting layer is formed by using the above-described method for forming a coated film, so that in forming the organic light emitting layer, it is possible to inhibit the elution of impurities or the like from the electric charge injection/transportation layer to the organic light emitting layer, or from the organic light emitting layer to the electric charge injection/transportation layer, to thereby allow the method for manufacturing the organic EL element to show the above-described effects.

Incidentally, in the present invention, there is provided the method for manufacturing the organic device, wherein the substrate has an electrode layer on its surface and has at least one-layer coated film made of an organic conductive layer on the electrode layer, any layer is formed by using coated compositions, and the at least one-layer coated film is formed by using the above-described method for forming a coated film.

Moreover, in the present invention, there is provided the method for manufacturing the organic EL element, wherein the substrate has an electrode layer on its surface and has a facing electrode layer which faces the electrode layer and which is laminated on an opposite side of the substrate of the electrode layer, each coated film of (i) at least one of a hole transportation layer and an electron transportation layer, as being an electric charge transportation layer, or (ii) at least one of a hole injection layer and an electron injection layer, as being an electric charge injection layer, and (iii) a light emitting layer is formed between the electrode layer and the facing electrode layer, from a side of the electrode layer, in order of the hole transportation layer, the hole injection layer, the light emitting layer, the electron injection layer, and the electron transportation layer, and a coated film in each of the layers is formed by using the above-described method for forming a coated film.

The above objects of the present invention can be also achieved by a method for forming a coated film, wherein after dissolution and removal of impurities are performed from a lower layer containing the solvent-soluble impurities by using a solvent which can dissolve the impurities, a coated film in an upper layer is formed onto the lower layer by using a coating composition for upper-layer formation.

In the present invention, after the solvent-soluble impurities contained in the lower layer (or a base layer) are dissolved and removed by using the solvent, the coated film in the upper layer is formed by using the coating composition for upper-layer formation, so that, in formation of the upper layer, it is possible to inhibit the elution of the impurities from the lower layer (or the base layer), and moreover, there is an advantage that there is no increase of the layer and no requirement for a long time in the purification process for the materials.

In another aspect of the method for forming a coated film, in forming at least two-layer coated films onto a substrate in order, after a coated film in the lower layer is formed by using a coating composition for lower-layer formation containing the solvent-soluble impurities, the dissolution and removal of the impurities may be performed, and then the coated film in the upper layer may be formed onto the coated film in the lower layer.

In the present invention, after the solvent-soluble impurities in the coated film in the lower layer are dissolved and removed by using the solvent, the coated film in the upper layer is formed, so that it is possible to inhibit the elution of the impurities from the lower layer, in forming the upper layer, and moreover, there is an advantage that there is no increase of the layer and no requirement for a long time in the purification process for the materials.

In this case, after the coated film in the upper layer is formed by using the coating composition for upper-layer formation containing solvent-soluble impurities, dissolution and removal of the impurities contained in the coated film in the upper layer may be performed. This is because, for example, if a coated film in a third layer is laminated onto the coated film in the upper layer, it is possible to inhibit the elution of the impurities from the upper layer, in forming the third layer.

In the above-described present invention, it is preferable that the solvent which can dissolve the impurities is the same as a solvent contained in the coating composition for upper-layer formation or has similar solubility to that of the solvent contained in the coating composition for upper-layer formation. This is because, in addition to the above-described effects, the impurities, which are likely eluted in forming the coated film in the upper layer, are dissolved and removed by using the solvent which is contained in the coating composition for upper-layer formation or which has similar solubility to that of the solvent contained in the coating composition for upper-layer formation, so that it is possible to inhibit the elution of the impurities from the lower layer, in forming the upper layer, and moreover, there is an advantage that there is no increase of the layer and no requirement for a long time in the purification process for the materials.

Moreover, in the present invention, it is preferable that the dissolution and removal are performed by contacting a coated film in the lower layer with the solvent which can dissolve the impurities. This is because, in addition to the above-described effects, the dissolution and removal are performed by contacting the coated film with the solvent, which is an easy implementation.

In this case, the dissolution and removal may be performed by dipping the coated film in the lower layer in the solvent which can dissolve the impurities. This is because, in addition to the above-described effects, the dissolution and removal are performed by dipping the coated film in the solvent, which is an easy operation and which certainly allows the dissolution and removal of the impurities.

In this case, it is preferable that the dissolution and removal are performed while applying ultrasonic wave. This is because, in addition to the above-described effects, ultrasonic wave is used in combination, so that the dissolution and removal can be efficiently performed for a short time.

Moreover, the dissolution and removal may be performed by spin coating the solvent which can dissolve the impurities onto the coated film in the lower layer. This is because, in addition to the above-described effects, widespread apparatuses can be used, so that a relatively small substrate can be targeted.

Moreover, in the present invention, it is preferable that the coated film in the lower layer contains polymer and a solvent which does not dissolve the polymer is used as the solvent which can dissolve the impurities. This is because, in addition to the above-described effects, the lower layer contains polymer, and that the solvent which does not dissolve the polymer is used in the dissolution and removal of the impurities, the dissolution and removal of the impurities can be performed without destroying the polymer in the lower layer.

The above objects of the present invention can be also achieved by a method for manufacturing an organic device comprising: a substrate; an electrode layer formed on the substrate; and an organic conductive layer which is formed on the electrode layer and which includes at least two-layer coated films, wherein the at least two-layer coated films in the organic conductive layer are formed by using the above-described method for forming a coated film.

In the present invention, the substrate with the electrode layer on its surface is used, and the above-described method for forming a coated film is used in forming at least two-layer coated films thereon, to thereby allow the method for manufacturing the organic device to show the above-described effects.

Moreover, the above objects of the present invention can be also achieved by a method for manufacturing an organic EL element comprising: a substrate; an electrode layer formed on the substrate; an organic conductive layer which is formed on the electrode layer and which includes the coated films of an electric charge injection/transportation layer and an organic light emitting layer formed on the electric charge injection/transportation layer; and a facing electrode layer which is formed on the organic conductive layer and which faces the electrode layer, wherein coated films of the electric charge injection/transportation layer and the organic light emitting layer are formed by using the above-described method for forming a coated film.

In the present invention, the coated films of the electric charge injection/transportation layer and the organic light emitting layer is formed by using the above-described method for forming a coated film, so that in forming the organic light emitting layer, it is possible to inhibit the elution of impurities or the like from the electric charge injection/transportation layer to the organic light emitting layer, or from the organic light emitting layer to the electric charge injection/transportation layer, to thereby allow the method for manufacturing the organic El element to show the above-described effects.

Incidentally, in the present invention, there is provided the method for manufacturing the organic device, wherein the substrate has an electrode layer on its surface and has at least two-layer coated films made of organic conductive layers are formed on the electrode layer, and the at least two-layer coated films are formed by using the above-described method for forming a coated film.

Moreover, in the present invention, there is provided the method for manufacturing the organic EL element, wherein the substrate has an electrode layer on its surface and has a facing electrode layer which faces the electrode layer and which is laminated on an opposite side of the substrate of the electrode layer, each coated film of (i) at least one of a hole transportation layer and an electron transportation layer, as being an electric charge transportation layer, or (ii) at least one of a hole injection layer and an electron injection layer, as being an electric charge injection layer, and (iii) a light emitting layer is formed between the electrode layer and the facing electrode layer, from a side of the electrode layer, in order of the hole transportation layer, the hole injection layer, the light emitting layer, the electron injection layer, and the electron transportation layer, and a coated film in each of the layers is formed by using the above-described method for forming a coated film.

### DESCRIPTION OF PREFERRED EMBODIMENTS

The present invention will be explained in detail hereinafter.

There are four embodiments into which the method for forming a coated film of the present invention is broadly divided, depending on a method for removing impurities or the like in a coated film. A first embodiment of the method for forming a coated film of the present invention is to dissolve and remove, in advance, impurities in a coating composition for forming a coated film, by using a solvent which can dissolve the impurities. Moreover, a second embodiment of the method for forming a coated film of the present invention is to perform the above-described dissolution and removal of impurities from a lower layer containing the solvent-soluble impurities by using the solvent which can dissolve the impurities, and then, form a coated film in an upper layer onto the lower layer. Moreover, a third embodiment of the method for forming a coated film of the present invention is a combination of the dissolution and removal in the first and second embodiments. Furthermore, a fourth embodiment of the method for forming a coated film of the present invention is to form a coated film by using a coating composition containing impurities, and then dissolve and remove the impurities in the coated film by using a solvent which can dissolve the impurities.

Each embodiment of the method for forming a coated film of the present invention will be explained hereinafter.

### 1. FIRST EMBODIMENT

The first embodiment of the method for forming a coated film of the present invention is characterized in that in forming a coated film onto a substrate, after impurities in a coating composition for forming the coated film are dissolved and removed in advance by using a solvent which can dissolve the impurities, the coated film is formed onto the substrate by using the coating composition in which the impurities are removed.

In another aspect of the method for forming a coated film in the present embodiment, it is possible that in forming at least two-layer coated films onto the substrate in order, after a coated film in a lower layer is formed by using the coating compositions in which the impurities are removed, a coated film in an upper layer is formed onto the coated film in the lower layer Incidentally, the “solvent” in the present invention indicates an organic solvent or water.

For example, a color-coating composition used for the formation of a color-coated film is uniformly prepared by providing, stirring, and mixing a binder resin, a coloring material, such as a pigment and a dye, a solvent, and various additives, mainly. It is desirable that each component in the color-coating composition is sufficiently purified. However, normally, each component is provided as it contains impurities to some extent because the purification requires a lot of energy and supplies.

Some of the coating composition may add another function other than coating the color-coated film onto a coating object. As the coating composition used in this case, the following can be given as an example: i.e., a coating composition that is prepared by providing a material for the additional function, which can add a function to the object by the coating, in place of or along with the coloring material, in addition to the binder resin, the solvent, and the various additives, mainly, as in the color-coating composition.

In the binder resin, there are low molecular components of lower degrees of polymerization (DP) in a DP distribution obtained in the synthesis, except polymers, which allows the binder resin to have solubility in an organic solvent and water. In addition, impurities including monomers, oligomers, a cross-linking agent, or a polymerization initiator or the like, which are used for the synthesis, may remain as they are or in a decomposed condition, in some cases. Moreover, even in the components other than the binder resin, impurities such as ingredients and a by-product in the synthesis may remain in some cases. These impurities may cause the deterioration of a coated film after the formation of the coated film. In addition, in laminating another coated film onto the above-described coated film, the impurities in the coated film in the lower layer is likely eluted and included in the coated film in the upper layer, due to a solvent contained in the color-coating composition for upper-layer formation. Thus, the impurities may cause the unexpected deterioration of the coated film in the upper layer.

In the present embodiment, when it becomes a problem is when the solvent in the coating composition for upper-layer formation dissolves the impurities in the coated film in the lower layer, so that originally, it is desirable not to contain components which are soluble in the solvent in the coating composition for upper-layer formation, in the coated film in the lower layer. Realistically, it is enough to elute the impurities from the coating composition for lower-layer formation, by using the same solvent as is provided for the coating composition for upper-layer formation. By this, in forming the upper layer, it is possible to inhibit the elution of the impurities in the coated film in the lower layer.

In this case, as the solvent for dissolving the impurities, which is used for the elution of the impurities from the coating composition for lower-layer formation, the solvent used for the coating composition for upper-layer formation is not necessarily used, and other solvents whose solubility is similar may be used. Of course, if the impurities in the coating composition for lower-layer formation are already known, it is also preferable to use a solvent having high solubility for the impurities.

As the solvent provided in various coating compositions, there are many solvents conceivable; for example, isopropanol in an alcohol type, toluene or xylene in an aromatic type, ethyl acetate or n-butyl acetate in an ester type, methyl ethyl ketone, methyl isobutyl ketone, or cyclohexanone in a ketone type, and the like are listed as its representative. Except the above solvents, an ether type, such as 1,2-dioxane, tetra hydro furan, and diglyme, is also frequently used from the viewpoint of dissolving a specific component and not preventing a curing or hardening reaction of the coated film. Moreover, if a water-soluble or water-dispersal resin is used, water may be used.

Therefore, if isopropanol is mainly used in the coating composition for upper-layer formation, it is conceivable to use isopropanol to elute the impurities in the coating composition for lower-layer formation, but it is also possible to use methanol and ethanol in the same alcohol type, in place of isopropanol. In the same manner, if toluene is used in the coating composition for upper-layer formation, toluene can be used, or instead, xylene or benzene can be used. If xylene is used, xylene can be used, or instead, toluene or benzene can be used. If methyl ethyl ketone is used in the coating composition for upper-layer formation, methyl ethyl ketone can be used, or instead, methyl isobutyl ketone or acetone can be used. If methyl isobutyl ketone or cyclohexanone is used, the same can be used, or instead, methyl ethyl ketone or acetone can be used. Moreover, if methanol or ethanol is used in the coating composition for upper-layer formation, water can be used to elute the impurities in the coating composition for lower-layer formation. If water is used in the coating composition for upper-layer formation, methanol or ethanol can be used to elute the impurities in the coating composition for lower-layer formation.

In the above solvents, the alternatively used solvent has similarity in terms of chemical structures, such as the same alcohol type and the same aromatic type, or has similar or larger solubility to dissolve a specific material (impurities). These are generically referred to as “solvents with similar solubility”.

Incidentally, except the exemplified solvents, there are other solvents which are frequently used for each usage or application of the coating compositions. For example, in a field in which 1,2-dioxane, tetra hydro furan, diglyme, and the like are used, any solvent out of them can be used for the elution of impurities, or instead, dimethyl ether, diethyl ether, or the like can be used.

The above-described solvents are generally used in the coating compositions, and relatively many polymers used in the coating compositions have solubility in these solvents. Thus, as the solvent used for the elution of the impurities in the coated composition for lower-layer formation, it is preferable to select and use a solvent which can dissolve not polymers in the coating composition for lower-layer formation but the low molecular components of low DP contained in the polymers. If polymers for preparing the coating composition for lower-layer formation are formed by using an aqueous solution or water dispersion and if polymers in the coating composition for upper-layer formation have solubility in a solvent whose polarity is not so high, it is easy to select a solvent which does not dissolve the polymers in the coating composition for lower-layer formation.

In order to elute the impurities in the coating composition for lower-layer formation, a solvent which can dissolve the impurities contained in the coating composition for lower-layer formation is added to the coating composition for lower-layer formation. They are sufficiently mixed by stirring by using the rotation of a propeller or the like, by shaking the entire container, or by applying ultrasonic wave, to thereby dissolve the impurities in the added solvent. Then, by decantation or the like, both the coating composition for lower-layer formation with the impurities eluted and the solvent with the impurities dissolved are separated. If necessary, it is preferable to repeat these operations to reduce the ratio of the impurities contained in the coating composition for lower-layer formation.

In this case, the solvent which can dissolve the impurities is preferably incompatible with a solvent in the coating composition for lower-layer formation. This is because the incompatibility between the solvent which can dissolve and remove the impurities and the solvent in the coating composition for lower-layer formation, facilitates the separation of the solvent used in the dissolution and removal of the impurities.

Incidentally, the “dissolution and removal” or “dissolve and remove” in the present invention does not necessarily mean the complete absence of the impurities of the object, but also includes the partial residual thereof.

As described above, after the lower layer is formed by using the coating compositions for lower-layer formation in which the impurities are removed, the upper layer is formed thereon by using the coating composition for upper-layer formation. Thus, it is possible to prevent the solvent in the coating composition for upper-layer formation from eluting the impurities in the coated film in the lower layer and from containing the impurities therein.

Incidentally, if a third layer is further laminated onto the upper layer obtained in the above manner, the third layer may be laminated after impurities in the coating composition for upper-layer formation are removed in the same manner. Namely, if the third layer is laminated onto the upper layer, it is preferable that after the coated film in the upper layer is formed by using a coating composition whose impurities are dissolved and removed.

It is highly effective if the method for forming a coated film in the present embodiment is applied to a method for manufacturing an organic device which is available as the organic EL element.

The method for the organic device is a method for manufacturing an organic device comprising: a substrate; an electrode layer formed on the substrate; and an organic conductive layer which is formed on the electrode layer and which includes at least one-layer coated film, wherein the at least one-layer coated film of the organic conductive layer is formed by using the method for forming a coated film in the present embodiment.

As the organic conductive layer in the present embodiment, for example, an organic light emitting layer in the organic EL element described later, an organic semi-conductive layer in an organic transistor, and the like, are listed.

Moreover, a method for manufacturing the organic EL element in the organic device is a method for manufacturing an organic EL element comprising: a substrate; an electrode layer formed on the substrate; an organic conductive layer which is formed on the electrode layer and which includes coated films of an electric charge injection/transportation layer and an organic light emitting layer formed on the electric charge injection/transportation layer; and a facing electrode layer which is formed on the organic conductive layer and which faces the electrode layer, wherein at least one of coated films of the electric charge injection/transportation layer and the organic light emitting layer is formed by using the method for forming a coated film in the present embodiment.

In the method for manufacturing the organic EL element as described above, the method for forming a coated film in the present embodiment is used in forming at least one-layer coated film in the organic conductive layer, i.e. the at least one of coated films of the electric charge injection/transportation layer and the organic light emitting layer, so that it is possible to inhibit the elution of impurities from the electric charge injection/transportation layer to the organic light emitting layer, or from the organic light emitting layer to the electric charge injection/transportation layer, thereby not to inhibit the function of the electric charge injection/transportation layer or the organic light emitting layer, which is advantageous.

The method for manufacturing the organic EL element as described above will be explained hereinafter.

In the present embodiment, as the electric charge injection/transportation layer, there are an electric charge transportation layer for transporting electric charges injected from an anode or a cathode into the organic light emitting layer, and an electric charge injection layer for injecting electric charges injected from the anode or the cathode into the organic light emitting layer.

As the electric charge transportation layer, there are a hole transportation layer having a function of transporting holes injected from the anode into the organic light emitting layer, and an electron transportation layer having a function of transporting electrons injected from the cathode into the organic light emitting layer. Moreover, as the electric charge injection layer, there are a hole injection layer having a function of injecting holes injected from the anode into the organic light emitting layer, and an electron injection layer having a function of injecting electrodes injected from the cathode into the organic light emitting layer.

In the present embodiment, the above-described effects are achieved if a coated film of the electric charge injection/transportation layer in the organic conductive layer and a coated film of the organic light emitting layer are laminated. Among them, it is highly effective if the electric charge transportation layer and the organic light emitting layer are laminated, and particularly, it is most effective if the hole transportation layer and the organic light emitting layer are laminated.

In this case, with respect to the electric charge injection/transportation layer and the organic light emitting layer, either layer may be formed first, from the electrode layer side. The at least two-layer coated films can be between the cathode and the anode and are used.

Moreover, the method for forming a coated film in the present embodiment can be also applied to manufacturing processes for the organic EL element, which include: a process of forming a hole injection layer by using a coating composition for hole-injection-layer formation, i.e. an aqueous solution of PEDOT/PSS, in which low molecular components of PEDOT or PSS are removed in advance by using a solvent; and a process of forming an organic light emitting layer onto the hole injection layer.

Furthermore, in forming the above-described organic light emitting layer, there is a possibility that not only the low molecular components of PSS, but also polymer components are eluted from the hole injection layer, to thereby deteriorate the function of the organic light emitting layer. Therefore, in such a case, on the assumption that the polymer components of PSS are also included in the impurities, PSS may be removed from the aqueous solution of PEDOT/PSS by using a solvent, in forming the hole injection layer.

As the substrate used in the present embodiment, an inorganic base material, such as glass, silicon, and quartz, and an appropriate organic base material are listed. As the organic base material, acrylic resins such as poly(methyl methacrylate), polyamide, polyacetal, poly(butylene terephthalate), poly(ethylene terephthalate), poly(ethylene naphthalate), triacetyl cellulose, syndiotactic-polystyrene and the like, poly(phenylene sulfide), polyetherketone, polyetheretherketone, fluorinated resins, polyethernitrile and the like, polycarbonate, modified polyphenyleneether, polycyclohexene, polynorbornene-based resins, or polysulfone, polyethersulfone, polysulfone, polyarylate, polyamideimide, polyetherimide, thermoplastic polyimide and the like, are listed, however, those made of general plastics can be also used.

The thickness of the substrate is not particularly limited, however, it can be set in a range of about 5μm to 1 mm, for example, depending on its usage.

With respect to the electrode layer, there are two cases: an anode and a cathode. Both a material for preparing the anode and a material for preparing the cathode are not particularly limited if used for normal organic EL elements.

If the electrode layer is the anode, particularly, a transparent or semitransparent conductive material having a large work function is preferable so as to easily inject holes. Specifically, for example, Indium Tin Oxide (ITO), Indium oxide, Gold, or Indium Zinc Oxide (IZO) are listed. The thickness of the anode is from about 10 to 500 nm, and the anode may be patterned by photoetching or the like, if necessary.

Moreover, if the electrode layer is the cathode, a conductive material having a small work function is preferable so as to easily inject electrons. Specifically, Magnesium alloy (MgAg), Aluminum, Silver, and the like are listed. The thickness of the cathode is preferably from about 10 nm to 1 μm, more preferably, from about 50 to 200 nm. Again, the cathode may be patterned by photoetching or the like, if necessary.

There may be partially an insulating layer on the substrate or on the anode. The insulating layer is preferably made of a cured material including photocuring resins, such as ultraviolet curing resins, or thermosetting resins. The insulating layer can be used as a black matrix by providing carbon black or the like.

The organic light emitting layer is between the both electrodes, and made of an organic fluorescent substance including dye-based, metal complex-based, and polymer-based fluorescent substances, which emits light by applying electric potential to the both electrodes.

As the dye-based organic fluorescent substance, cyclopentamine derivatives, tetraphenylbutadiene derivatives, triphenylamine derivatives, oxadiazole derivatives, pyrazoloquinoline derivatives, distyrylbenzene derivatives, distyrylarylene derivatives, silol derivatives, thiophene ring compounds, pyridine ring compounds, perynone derivatives, perylene derivatives, oligothiophene derivatives, trifumanylamine derivatives, oxaziazole dimer, pyrazoline dimer and the like are listed.

As the metal complex-based organic fluorescent substance, metal complexes which have Al, Zn, Be and the like or a rare earth metal, such as Tb, Eu, Dy and the like, as the center metal and which have oxadiazole, thiadiazole, phenylpyridine, phenylbenzimidazole, quinoline structure and the like as the ligand, such as an alumiquinolinol complex, a benzoquinolinolberyllium complex, a benzooxazolezinc complex, a benzothiazolezinc complex, an azomethylzinc complex, a porphyrinzinc complex, an europium complex and the like are listed.

As the polymer-based organic fluorescent substance, poly-p-phenylenevinylene derivatives, polythiophene derivatives, poly-p-phenylene derivatives, polysilane derivatives, polyacetylene derivatives, polyfluorene derivatives, polyvinylcarbazole derivatives, those obtained by polymerizing the above-mentioned dye-based organic fluorescent substance or metal complex-based light emitting materials, and the like are listed.

Moreover, doping can be performed for the purpose of improving light emitting efficiency in the organic light emitting layer, changing a light emitting wavelength, or the like. As this doping material, for example, perylene derivatives, coumarin derivatives, quinacridone derivatives, squalirium derivatives, porphyrin derivatives, styryl-based dyes, tetracene derivatives, pyrazoline derivatives, decacyclene, phenoxazone and the like are listed.

In principle, the organic EL element produced by using the method for forming a coated film in the present embodiment emits light if there is the organic light emitting layer between the both electrodes. However, the hole transportation layer may be laminated between the anode and the organic light emitting layer, or the electron transportation layer may be laminated between the cathode and the organic light emitting layer, from a meaning to promote the transportation of holes and/or electrons to the organic light emitting layer. Moreover, if the hole transportation layer is laminated, the hole injection layer may be laminated between the anode and the hole transportation layer, and if the electron transportation layer is laminated, the electron injection layer may be laminated between the cathode and the electron transportation layer. The hole transportation layer, the hole injection layer, the electron transportation layer, and the electron injection layer may be made of the following materials.

As the material for making the hole transportation layer, for example, triphenylamines, bis-compounds, heterocyclic compounds represented by pyrazoline derivatives and porphyrin derivatives, and in the polymer-based material, polycarbonate having the above monomer in the side chain, styrene derivatives, poly(vinyl carbazole), polysilane and the like are listed.

As the material for making the hole injection layer, for example, phenylamine-based, starburst type amine-based, phthalocyanine-based, oxides such as Vanadium Oxide, Molybdenum Oxide, Ruthenium Oxide, and Aluminum Oxide, amorphous carbon, polyaniline, polythiophen derivatives, and the like are listed.

As the material for making the electron transportation layer, for example, materials which can form generally stable radical anions and whose ionization potential is high, such as oxadiazoles and an aluminum quinolinol complex, are listed. Specifically, 1,3,4-oxadiazole derivatives, 1,2,4-triazole derivatives, and the like are listed.

As the material for making the electron injection layer, for example, metal in the IA or IIA family, oxides thereof, or halides thereof are preferable. As examples of metal in the IA family, oxides thereof, or halides thereof, specifically, Lithium Fluoride, Sodium Oxide, Lithium Oxide and the like are listed. As examples of metal in the IIA family, oxides thereof, or halides thereof, specifically, Strontium, Magnesium Oxide, Magnesium Fluoride, Strontium Fluoride, Calcium, Calcium Fluoride, Barium Fluoride, Strontium Oxide, and the like are listed.

Obviously, the method for forming a coated film in the present embodiment can be applied to recoating which uses the color-coating compositions, and can be broadly applied in recoating the coating compositions which contain various functional materials.

### 2. SECOND EMBODIMENT

The second embodiment of the method for forming a coated film of the present invention is characterized in that after dissolution and removal of solvent-soluble impurities are performed from a lower layer containing the impurities by using a solvent which can dissolve the impurities, a coated film in an upper layer is formed onto the lower layer by using a coating composition for upper-layer formation.

Moreover, in another aspect of the method for forming a coated film in the present embodiment, it is possible that in forming at least two-layer coated films onto a substrate in order, after a coated film in the lower layer is formed by using a coating composition for lower-layer formation containing the solvent-soluble impurities, and then the coated film in the upper layer is formed onto the coated film in the lower layer.

Incidentally, the “solvent” in the present invention indicates an organic solvent or water, and the “solvent-soluble” indicates “organic-solvent-soluble” or “water-soluble”.

As described in the first embodiment, the coating composition for forming a coated film contains impurities. These impurities may cause the deterioration of a coated film after the formation of the coated film. In addition, in laminating another coated film onto the above-described coated film, the impurities in the coated film in the lower layer is likely eluted and included in the coated film in the upper layer, due to a solvent contained in the coating composition for upper-layer formation. Thus, the impurities may cause the unexpected deterioration of the coated film in the upper layer.

In the present embodiment, when it becomes a problem is when the solvent in the coating composition for upper-layer formation dissolves the impurities in the coated film in the lower layer, so that originally, it is desirable not to contain components which are soluble in the solvent in the coating composition for upper-layer formation, in the coated film in the lower layer. Realistically, it is enough to elute the impurities from the coated film in the lower layer, by using the same solvent as is provided for the coating composition for upper-layer formation. By this, in forming the upper layer, it is possible to inhibit the elution of the impurities in the coated film in the lower layer.

In this case, as the solvent for dissolving the impurities, which is used for the elution of the impurities from the coated film in the lower layer, the solvent used for the coating composition for upper-layer formation is not necessarily used, and other solvents whose solubility is similar may be used. Of course, if the impurities in the coated film in the lower layer are already known, it is also preferable to use a solvent having high solubility for the impurities.

Incidentally, with respect to the solvent which can dissolve the impurities, the same solvents as described in the first embodiment can be used, so that their explanations are omitted here.

The above-described solvents are generally used in the coating compositions, and relatively many binder resins used in the coating compositions have solubility in these solvents. Thus, as the solvent used for the elution of the impurities in the coated film in the lower layer, it is preferable to select and use a solvent which does not dissolve binder resins in the coated film in the lower layer. If binder resins for preparing the coated film in the lower layer is formed by using an aqueous solution or water dispersion and if binder resins in the coating composition for the upper layer formation have solubility in a solvent whose polarity is not so high, it is easy to select a solvent which does not dissolve the binder resins in the coated film in the lower layer.

Moreover, the binder resins may contain low molecular components of low DP generated in the synthesis except polymers, so that as the above-described solvents, it is more preferable to use a solvent which does not dissolve polymers in the coated film in the lower layer.

In order to elute the impurities in the coated film in the lower layer, there is a method in which the coated film in the lower layer is first formed onto an appropriate substrate by using a coating composition for lower-layer formation, and then, a solvent which can dissolve the impurities in the coated film in the lower layer is used for coating, spraying, poring, or the like, with respect to the coated film in the lower layer laminated on the substrate, to thereby contact the solvent which can dissolve the impurities in the coated film. From a meaning to promote the elution of the impurities, it is possible to perform the above method while rubbing a surface of the coated film in the lower layer to an extent not damaging the coated film.

As one example of the method for contacting the solvent which can dissolve the impurities, there is a method in which after the solvent which can dissolve the impurities is dropped onto the coated film in the lower layer, which is laminated on the substrate by using a spinner, the sample is left for a while. According to this method, there is an advantage that the solvent without the pollution of the impurities can be used each time. Alternatively, as another example of the method for contacting the solvent which can dissolve the impurities, there is a method in which a lamination of the coated film in the lower layer on the substrate is dipped in the solvent. In the dipping method, ultrasonic wave can be applied to promote the elution of the impurities. In any methods, the warming of the substrate by an appropriate device, the warming of the solvent, or the like is preferably performed to improve the solubility of the impurities in the solvent.

Moreover, contacting the solvent which can dissolve the impurities with the coated film in the above-described various methods may be performed not only once but also twice or more. In the case of twice or more contacts, it is possible to combine different methods selected from the above-described various methods.

Incidentally, even a substrate without a coated film on its surface may contain impurities which are soluble in solvents or water, so that the impurities can be eluted even from the substrate of this type, in the same manner as the above-described processes for the coated film in the lower layer.

After the contact with the solvent which can dissolve the impurities, the coated film in the lower layer is dried, and the solvent which attaches or penetrates the lower layer to some extent is removed. The removal of the solvent may be performed by leaving it to stand, air-drying, or heating. After the removal of the solvent, the upper layer is formed by using the coating composition for upper-layer formation. Thus, it is possible to prevent the solvent in the coating composition for upper-layer formation from eluting the impurities in the coated film in the lower layer and from containing the impurities therein.

Incidentally, if a third layer is further laminated onto the upper layer obtained in the above manner, the third layer may be laminated after impurities in the coated film in the upper layer is removed in the same manner. Namely, if the third layer is laminated onto the upper layer, it is preferable that after the coated film in the upper layer is formed by using the coating composition for upper-layer formation containing solvent-soluble impurities, the impurities contained in the coated film in the upper layer are dissolved and removed.

It is highly effective if the method for forming a coated film in the present embodiment is applied to a method for manufacturing an organic device which is available as the organic EL element.

The method for manufacturing the organic device is a method for manufacturing an organic device comprising: a substrate; an electrode layer formed on the substrate; and an organic conductive layer which is formed on the electrode layer and which includes at least two-layer coated films, wherein the at least two-layer coated films in the organic conductive layer are formed by using the above-described method for forming a coated film.

As the organic conductive layer in the present embodiment, for example, an organic light emitting layer in the organic EL element described later, an organic semi-conductive layer in an organic transistor, and the like, are listed.

Moreover, a method for manufacturing the organic EL element in the organic device is a method for manufacturing an organic EL element comprising: a substrate; an electrode layer formed on the substrate; an organic conductive layer which is formed on the electrode layer and which includes coated films of an electric charge injection/transportation layer and an organic light emitting layer formed on the electric charge injection/transportation layer; and a facing electrode layer which is formed on the organic conductive layer and which faces the electrode layer, wherein coated films of the electric charge injection/transportation layer and the organic light emitting layer is formed by using the method for forming a coated film in the present embodiment.

In the method for manufacturing the organic EL element as described above, the method for forming a coated film in the present embodiment is used in forming at least two-layer coated films in the organic conductive layer, i.e. the coated films of the electric charge injection/transportation layer and the organic light emitting layer, so that it is possible to inhibit the elution of impurities from the electric charge injection/transportation layer to the organic light emitting layer, or from the organic light emitting layer to the electric charge injection/transportation layer, thereby not to inhibit the function of the electric charge injection/transportation layer or the organic light emitting layer, which is advantageous.

Incidentally, other points of the method for manufacturing the organic EL element which uses the method for forming a coated film in the present embodiment are the same as those described in the first embodiment, so that their explanations are omitted here.

### 3. THIRD EMBODIMENT

The third embodiment of the method for forming a coated film of the present invention is a combination of the dissolution and removal in the first and second embodiments. The method for forming a coated film in the present embodiment can be divided into two aspects depending on the combination of the dissolution and removal in the first and second embodiments.

In a first aspect of the method for forming a coated film in the present embodiment, in forming at least two-layer coated films onto a substrate in order, after impurities in a coating composition for lower-layer formation are dissolved and removed by using a solvent which can dissolve the impurities, a coated film in a lower layer is formed by using the coating composition for lower-layer formation in which the impurities are removed, and then after a coated film in an upper layer is formed onto the coated film in the lower layer by using a coating composition for upper-layer formation containing solvent-soluble impurities, dissolution and removal of the impurities are performed from the coated film in the upper layer by using a solvent which can dissolve the impurities.

Moreover, in a second aspect of the method for forming a coated film in the present embodiment, in forming at least two-layer coated films onto a substrate in order, after a coated film in a lower layer is formed by using a coating composition for lower-layer formation containing solvent-soluble impurities, dissolution and removal of the impurities are performed from the coated film in the lower layer by using a solvent which can dissolve the impurities, and then, after impurities in a coating composition for upper-layer formation are dissolved and removed by a solvent which can dissolve the impurities, a coated film in an upper layer is formed onto the coated film in the lower layer by using the coating composition for upper-layer formation in which the impurities are removed.

According to the present embodiment, in any aspects, the impurities are dissolved and removed from the coated film in the lower layer, so that it is possible to inhibit the elution of the impurities from the lower layer in forming the upper layer, and moreover, there is an advantage that there is no increase of the layer and no requirement for a long time in the purification process for the materials. Furthermore, the impurities are dissolved and removed even from the coated film in the upper layer, so that if a third layer is laminated onto the upper layer, for example, it is possible to inhibit the elution of the impurities from the upper layer, in forming the third layer.

Incidentally, other points of the method for forming a coated film in the present embodiment are the same as those described in the first and second embodiments, so that their explanations are omitted here.

The method for forming a coated film in the present embodiment is preferably used for a method for manufacturing an organic device, such as the organic EL elements, as in the first and second embodiments.

### 4. FOURTH EMBODIMENT

The fourth embodiment of the method for forming a coated film of the present invention is characterized in that in forming a coated film onto a substrate, the coated film is formed on the substrate by using a coating composition containing solvent soluble impurities, and then the impurities in the coated film are dissolved and removed from the coated film by using a solvent which can dissolve the impurities.

According to the present embodiment, the solvent-soluble impurities in the coated film are dissolved and removed by using a solvent, so that it is possible to inhibit the elution of the impurities from the coated film. Moreover, there is an advantage that there is no increase of the layer and no requirement for a long time in the purification process for the materials. Furthermore, if a second coated film is laminated on the coated film, it is possible to inhibit the elution of the impurities from the coated film, in forming the second coated film.

Incidentally, other points of the method for forming a coated film in the present embodiment are the same as those described in the second embodiment, so that their explanations are omitted here.

Moreover, the method for forming a coated film in the present embodiment is preferably used for a method for manufacturing an organic device, such as the organic EL elements, as in the first and second embodiments.

Incidentally, the present invention is not limited to the above-described embodiments. The above-described embodiments are only examples, and any embodiments having substantially the same constitution and performing the same action and effect as the technological idea described in Claims of the present invention are included in the technological range of the present invention.

### EXAMPLES

The following examples will further illustrate the present invention.

### Example 1

10 cm³ of xylene was added to 10 cm³ of an aqueous solution of poly(ethylenedioxythiophene)/poly(styrene sulfonate) (abbreviation; PEDOT/PSS) (manufactured by Bayer AG, an aqueous solution of resins for forming a hole translation layer, commercial name; “Baytron P CH8000”), and the mixture was shaken with a shaker for 1 hour and left to stand. The mixture was separated into an aqueous phase and a xylene phase. The Xylene phase was colored, so that it was confirmed that low molecular components of PEDOT or PSS were dissolved in xylene. Then, the mixture was separated by decantation. By these treatments, the xylene-soluble components in the aqueous solution of PEDOT/PSS were dissolved and removed.

An ITO thin film pattern was prepared on a glass substrate. After a cleaning process and a UV-plasma cleaning process are performed, the aqueous solution of PEDOT/PSS to which the treatments in the previous paragraph had been conducted was spin coated onto the ITO thin film pattern, heated and dried for 30 minutes on a hot plate set to 200° C., to thereby form a hole transportation layer. Incidentally, the number of revolutions in the spin coating was adjusted to obtain the hole transportation layer having a thickness of 70 nm.

On the above-described hole transportation layer, a composition for forming a light emitting layer described below was spin coated for each color of light emission, and then, dried at 80° C., to thereby form an organic light emitting layer having a thickness of about 80 nm. After the formation of the organic light emitting layer, a LiF thin film was formed to have a thickness of about 1 nm, and then Ca was formed to have a thickness of 10 nm. Lastly, Al was formed to have a thickness of 200 nm. The sample was sealed by sealing glass, to thereby obtain an organic EL element.

<Composition for Forming Light Emitting Layer>

| | | |
|---|---|---|
| polyvinylcarbazole | 7 | parts by weight |
| Light emitting dye | 0.1 | part by weight |
| (For red, green, or blue; see the Note below) | | |
| Oxadiazole compound | 3 | parts by weight |
| Toluene | 1500 | parts by weight |
| Tetralin | 2500 | parts by weight |

Note;
Used as the light emitting dye are for red; Nile red, for green; Coumarin 6, and for blue; Perylene compound.

For comparison, another organic EL element was obtained in the same manner as described above, without the dissolution and removal of the xylene-soluble components in the aqueous solution of PEDOT/PSS.

Light emissions of the obtained organic EL elements were compared. As compared to the organic EL element prepared by using the aqueous solution of PEDOT/PSS without the dissolution and removal of the xylene-soluble components, the organic EL element prepared by using the aqueous solution of PEDOT/PSS from which the xylene-soluble components had been dissolved and removed, improved the element lifetime: 1.5 times longer in a red light emitting layer, 1.3 times longer in a green light emitting layer, and 1.1 times longer in a blue light emitting layer.

### Example 2

In the same manner as in Example 1, a hole transportation layer was formed on a glass substrate having an ITO thin film pattern thereon after the dissolution and removal of xylene-soluble components in an aqueous solution of PEDOT/PSS.

On the above-described hole transportation layer, a composition for forming a light emitting layer described below was spin coated for 10 seconds at 1500 rpm, and dried for about 1 hour on a hot plate set to 130° C., to thereby form an organic light emitting layer. Moreover, after the formation of the organic light emitting layer, as in Example 1, thin films of LiF, Ca, and Al were formed in this order. The sample was sealed by sealing glass, to thereby obtain an organic EL element.

<Composition for Forming Light Emitting Layer>

| | |
|---|---|
| polyfluorene derivatives (manufactured by ADS | 1 parts by weight |
| Inc., ADS 228GE) | |
| Xylene (manufactured by Kanto Chemical Corp., | 99 parts by weight |
| EL Grade) | |

For comparison, another organic EL element was obtained in the same manner as described above, without the dissolution and removal of the xylene-soluble components in the aqueous solution of PEDOT/PSS.

Light emissions of the obtained organic EL elements were compared. As compared to an element life time of about 1500 hours in the organic EL element prepared by using the aqueous solution of PEDOT/PSS without the dissolution and removal of the xylene-soluble components, the organic EL element prepared by using the aqueous solution of PEDOT/PSS from which the xylene-soluble components had been dissolved and removed, improved the element lifetime, which was about 1800 hours.

### Example 3

An ITO thin film pattern was prepared on a glass substrate. After a cleaning process and a UV-plasma cleaning process are performed, poly(ethylenedioxythiophene)/poly(styrene sulfonate) (manufactured by Bayer AG, an aqueous dispersion of resins for forming a hole translation layer, commercial name; “Baytron P CH8000”) was spin coated onto the ITO thin film pattern, heated and dried for 30 minutes on a hot plate set to 200° C. Incidentally, the number of revolutions in the spin coating was adjusted to obtain a coated film having a thickness of 70 nm. In this manner, a laminated structure of glass substrate/transparent electrode layer/hole transportation layer was obtained. The obtained substrate is referred to as a substrate A.

With respect to the substrate A, the following operations were performed by using xylene as a solvent. First, the substrate A was dipped in xylene which was being stirred in a container, and 5 minutes later, taken out and dried. The obtained substrate by this operation is referred to as a substrate B. Moreover, the substrate A was dipped in xylene in a container, and cleaned by ultrasonic wave for 5 minutes, at an oscillation frequency of 38 KHz, with an output of 120 W. The obtained substrate by this operation is referred to as a substrate C. Moreover, xylene was dropped onto the substrate A set on a spinner, and the sample was left to stand for 1 minute for the dissolution, and then xylene was removed by high-speed spinning. The obtained substrate by this operation is referred to as a substrate D. In any cases, the temperature of xylene was room temperature (25° C.).

On the hole transportation layer side of each of the substrates A to D, a composition for forming a light emitting layer described below was spin coated for each color of light emission, and then, dried at 130° C., to thereby form an organic light emitting layer having a thickness of about 80 nm. After the formation of the organic light emitting layer, a LiF thin film was formed to have a thickness of about 1 nm, and then Ca was formed to have a thickness of 10 nm. Lastly, Al was formed to have a thickness of 200 nm. The samples were sealed by sealing glass, to thereby obtain organic EL elements.

<Composition for Forming Light Emitting Layer>

| | | |
|---|---|---|
| polyvinylcarbazole | 7 | parts by weight |
| Light emitting dye | 0.1 | part by weight |
| (For red, green, or blue; see the Note below) | | |
| Oxadiazole compound | 3 | parts by weight |
| Toluene | 1500 | parts by weight |
| Tetralin | 2500 | parts by weight |

Note;
Used as the light emitting dye are for red; Nile red, for green; Coumarin 6, and for blue; Perylene compound.

Light emissions of the organic EL elements, which were obtained by using the above-described composition for forming a light emitting layer for each color of light emission to the substrate A to D, were compared. In the organic EL element obtained by using the substrate A, the improvement of the element lifetime was not observed. It was found, however, that the element lifetimes improved in the organic EL elements obtained by using the substrate B, the substrate C, and the substrate D. Incidentally, the substrate B and the substrate C were excellent among the substrate B, the substrate C, and the substrate D.

### Example 4

On the hole transportation layer side of each of the substrates A to D in Example 3, a composition for forming a light emitting layer described below was spin coated for 10 seconds at 1500 rpm, and dried for about 1 hour on a hot plate set to 130° C., to thereby form an organic light emitting layer. Moreover, after the formation of the organic light emitting layer, as in Example 3, thin films of LiF, Ca, and Al were formed in this order. The samples were sealed by sealing glass, to thereby obtain organic EL elements.

<Composition for Forming Light Emitting Layer>

| | |
|---|---|
| polyfluorene derivatives (manufactured by ADS | 1 parts by weight |
| Inc., ADS 228GE) | |
| Xylene (manufactured by Kanto Chemical Corp.,) | 99 parts by weight |
| EL Grade | |

Light emissions of the organic EL elements, which were obtained by using the above-described composition for forming a light emitting layer for each color of light emission to the substrate A to D, were compared. As compared to an element life time of about 1500 hours in the organic EL element prepared by using the substrate A, the organic EL elements prepared by using the substrate B and the substrate C had an element lifetime of about 2200 hours, and the organic EL elements prepared by using the substrate D had an element lifetime of about 1800 hours. The results showed that the use of the substrate B, the substrate C, and the substrate D, to which the dissolution and removal was performed by using xylene, improved the element lifetime. Incidentally, the substrate B and the substrate C were excellent among the substrate B, the substrate C, and the substrate D.

[Evaluation Method for Element Lifetime]

The element lifetime was evaluated in the following manner.

The value of an electric current applied to the organic EL element is set so that the organic EL element emits light at 100 nit, and the organic EL element is kept driving under the constant electric current value. Then, when the increase of the voltage, the degradation of brightness, or the like occur, regardless of the constant electric current value, to thereby reduce the brightness to 50 nit (a half value of the initial brightness of 100 nit), a time length until the reduction is regarded as the element lifetime.

1. A method for forming a coated film, wherein in forming the coated film onto a substrate, after impurities in a coating composition for forming the coated film are dissolved and removed in advance by using a solvent which can dissolve the impurities, the coated film is formed onto the substrate by using the coating composition in which the impurities are removed.

2. The method for forming a coated film according to claim 1, wherein in forming at least two-layer coated films onto the substrate in order, after a coated film in a lower layer is formed by using the coating compositions in which the impurities are dissolved and removed, a coated film in an upper layer is formed onto the coated film in the lower layer.

3. The method for forming a coated film according to claim 2, wherein the coated film in the upper layer is formed by using the coating composition in which the impurities are dissolved and removed.

4. The method for forming a coated film according to claim 1, wherein the solvent which can dissolve the impurities is incompatible with a solvent in the coating composition.

5. The method for forming a coated film according to claim 1, wherein the coating composition contains polymer which may include low molecular components as impurities, and the solvent which can dissolve the impurities does not dissolve the polymer.

6. A method for manufacturing an organic device comprising: a substrate; an electrode layer formed on the substrate; and an organic conductive layer which is formed on the electrode layer and which includes at least one-layer coated film,
wherein the at least one-layer coated film of the organic conductive layer is formed by using the method for forming a coated film according to claim 1.

7. A method for manufacturing an organic electroluminescent (EL) element comprising: a substrate; an electrode layer formed on the substrate; an organic conductive layer which is formed on the electrode layer and which includes coated films of an electric charge injection/transportation layer and an organic light emitting layer formed on the electric charge injection/transportation layer; and a facing electrode layer which is formed on the organic conductive layer and which faces the electrode layer,
wherein at least one of coated films of the electric charge injection/transportation layer and the organic light emitting layer is formed by using the method for forming a coated film according to claim 1.

8. A method for forming a coated film, wherein after dissolution and removal of impurities are performed from a lower layer containing the solvent-soluble impurities by using a solvent which can dissolve the impurities, a coated film in an upper layer is formed onto the lower layer by using a coating composition for upper-layer formation.

9. The method for forming a coated film according to claim 8, wherein in forming at least two-layer coated films onto a substrate in order, after a coated film in the lower layer is formed by using a coating composition for lower-layer formation containing the solvent-soluble impurities, the dissolution and removal of the impurities are performed, and then the coated film in the upper layer is formed onto the coated film in the lower layer.

10. The method for forming a coated film according to claim 9, wherein after the coated film in the upper layer is formed by using the coating composition for upper-layer formation containing solvent-soluble impurities, dissolution and removal of the impurities contained in the coated film in the upper layer are performed.

11. The method for forming a coated film according to claim 8, wherein the solvent which can dissolve the impurities is the same as a solvent contained in the coating composition for upper-layer formation or has similar solubility to that of the solvent contained in the coating composition for upper-layer formation.

12. The method for forming a coated film according to claim 8, wherein the dissolution and removal are performed by contacting a coated film in the lower layer with the solvent which can dissolve the impurities.

13. The method for forming a coated film according to claim 12, wherein the dissolution and removal are performed by dipping the coated film in the lower layer in the solvent which can dissolve the impurities.

14. The method for forming a coated film according to claim 13, wherein the dissolution and removal are performed while applying ultrasonic wave.

15. The method for forming a coated film according to claim 12, wherein the dissolution and removal are performed by spin coating the solvent which can dissolve the impurities onto the coated film in the lower layer.

16. The method for forming a coated film according to claim 9, wherein the coated film in the lower layer contains polymer and a solvent which does not dissolve the polymer is used as the solvent which can dissolve the impurities.

17. A method for manufacturing an organic device comprising: a substrate; an electrode layer formed on the substrate; and an organic conductive layer which is formed on the electrode layer and which includes at least two-layer coated films,
wherein the at least two-layer coated films in the organic conductive layer are formed by using the method for forming a coated film according to claim 9.

18. A method for manufacturing an organic EL element comprising: a substrate; an electrode layer formed on the substrate; an organic conductive layer which is formed on the electrode layer and which includes the coated films of an electric charge injection/transportation layer and an organic light emitting layer formed on the electric charge injection/transportation layer; and a facing electrode layer which is formed on the organic conductive layer and which faces the electrode layer,
wherein coated films of the electric charge injection/transportation layer and the organic light emitting layer are formed by using the method for forming a coated film according to claim 9.
